(19) United States
(12) Patent Application Publication
(10) Pub. No.: US 2006/0008746 A1
(43) Pub. Date: Jan. 12, 2006

(54) Method for manufacturing semiconductor device

(76) Inventors: Yasunobu Onishi, Yokohama-shi (JP); Kenji Chiba, Tokyo (JP); Daisuke Kawamura, Yokohama-shi (JP); Shinichi Ito, Yokohama-shi (JP); Koutaro Sho, Yokohama-shi (JP); Tomoyuki Takeishi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/174,720

(22) Filed: Jul. 6, 2005

(30) Foreign Application Priority Data
Jul. 7, 2004 (JP) 2004-200611
Oct. 20, 2004 (JP) 2004-306053
May 13, 2005 (JP) 2005-141192

(51) Int. Cl. G03F 7/00

(52) U.S. Cl. 430/322; 430/330

(57) ABSTRACT

The present application provides a method for manufacturing a semiconductor device, the method including forming a resist film on a substrate, forming a protective film on the resist film, exposing the resist film with a first liquid interposed between the protective film and a lens for exposure, removing the protective film using an oxidative second liquid after exposing the resist film, and developing the resist film to form a resist pattern after removing the protective film.

### CROSS-REFERENCE TO RELATED APPLICATIONS

This application is based upon and claims the benefit of priority from prior Japanese Patent Applications No. 2004-200611, filed Jul. 7, 2004; No. 2004-306053, filed Oct. 20, 2004; and No. 2005-141192, filed May 13, 2005, the entire contents of all of which are incorporated herein by reference.

### BACKGROUND OF THE INVENTION

1. Field of the Invention

The present invention relates to a method for manufacturing a semiconductor device.

2. Description of the Related Art

To cope with a reduction in the sizes of semiconductor devices and an increase in the degree of integration of semiconductor devices, what is called an immersion lithography has been proposed in which exposure is carried out with a liquid such as water interposed between a resist film and a lens of an exposure apparatus. However, with the immersion lithography method, the surface of the resist film is immersed directly in the liquid such as water. Thus, components of the resist film are eluted into the liquid such as water. This disadvantageously prevents an appropriate resist pattern from being obtained.

To avoid this problem, a protective film must be formed on the resist film to protect the resist film from the liquid such as water. A method has been proposed which uses, for example, a fluoro polymer as a protective film and a fluoro solvent as a stripper for the protective film. However, to recover the fluoro solvent used as a stripper, a dedicated expensive waste water treatment system must be constructed. This is a major factor increasing manufacturing costs. Further, another method has been proposed which uses, as a protective film, a film that can be stripped off by an alkaline developer. However, the use of such a film precludes the permeation of the liquid such as water from being sufficiently prevented.

Jpn. Pat. Appln. KOKAI Publication No. 5-74700 proposes a method of forming an antireflection coating on the surface of a photoresist film, the coating consisting of a fluoro polymer. However, this proposal uses a fluoro solvent as a stripper for the fluoro polymer. Further, with this proposal, the antireflection coating is not used as a protective film for immersion lithography.

Thus, the immersion lithography method has been proposed in order to meet requirements for a reduction in the sizes of semiconductor devices and an increase in the degree of integration of semiconductor devices. However, this method have problems such as the need for a dedicated expensive waste water treatment system used to recover the stripper for the protective film and the difficulty in providing a protective film having a sufficient protect function.

Jpn. Pat. Appln. KOKAI Publication No. 10-303114 discloses an apparatus in which a substrate to be treated is entirely submerged in water supplied into a stage and in which exposure is carried out while moving the stage relative to an exposure apparatus. However, with this apparatus, since the whole stage is supplied with the liquid, the liquid disadvantageously overflows the stage when the stage is moved at a high speed. Consequently, high speed movement is impossible.

To deal with the disturbance of the liquid resulting from the movement of the stage, a technique has been proposed in which the stage is moved while locally supplying a liquid to an exposed part (Soichi Owa and Hiroyuki Nagasaka, Immersion lithography; its potential performance and issues, Proc. of SPIE Vol. 5040, pp. 724-733). This method enables the stage to be moved at a high speed. However, when such a technique of locally supplying a liquid is used, water may be left in an exposed area or the like after movement of a lens. Consequently, when the resist film is subjected to post-exposure baking, problems may occur such as the occurrence of water marks and a decrease in temperature in areas in which water is present, resulting in an abnormal resist pattern.

Further, with the immersion lithography, it is known that components of the resist film may be leached into the liquid (Keita Ishizuka et al., New Cover material Development Status for Immersion lithography, Web publication of International symposium on immersion and 157 nm lithography). According to this document, such leaching can be avoided by providing a protective film on the surface of the resist film. The document also states that the contact angle at which the surface of the protective film contacts water is preferably at least 90°. However, the contact angle at which the protective film contacts water is about 68° to about 118°. Films ranging from a slightly hydrophilic one to a hydrophobic one are used for an ArF resist.

### BRIEF SUMMARY OF THE INVENTION

According to a first aspect of the present invention, there is provided a method for manufacturing a semiconductor device, the method including: forming a resist film on a substrate; forming a protective film on the resist film; exposing the resist film with a first liquid interposed between the protective film and a lens for exposure; removing the protective film using an oxidative second liquid after exposing the resist film; and developing the resist film to form a resist pattern after removing the protective film.

According to a second aspect of the present invention, there is provided a method for manufacturing a semiconductor device, the method including: forming a resist film on a substrate; forming a protective film on the resist film; exposing the resist film with a first liquid interposed between the protective film and a lens for exposure; modifying the protective film using a second liquid after exposing the resist film; removing the modified protective film using a third liquid; and developing the resist film to form a resist pattern after removing the modified protective film.

According to a third aspect of the present invention, there is provided a method for manufacturing a semiconductor device, the method including: forming a resist film on a substrate; forming a protective film on the resist film; exposing the resist film with a first liquid at a first temperature interposed between the protective film and a lens for exposure; removing the protective film using a second liquid after exposing the resist film, the second liquid being of the same type as that of the first liquid and having a second temperature higher than the first temperature; and developing the resist film to form a resist pattern after removing the protective film.

According to a fourth aspect of the present invention, there is provided a method for manufacturing a semiconductor device, the method including: forming a resist film on a substrate, wherein a contact angle between the resist film and an immersion liquid is a first angle; forming a protective film on the resist film, wherein a contact angle between a surface of the protective film and the immersion liquid is a second angle smaller than the first angle; modifying the surface of the protective film to form a high contact angle layer, wherein a contact angle between the high contact angle layer and the immersion liquid is a third angle larger than the second angle; forming a latent image in the resist film by immersion type exposure using the immersion liquid after forming the high contact angle layer; heating the resist film after forming the latent image; removing the high contact angle layer after forming the latent image; removing the protective film after removing the high contact angle layer; and developing the resist film to form a resist pattern after heating the resist film and after removing the protective film.

According to a fifth aspect of the present invention, there is provided a method for manufacturing a semiconductor device, the method including: forming a resist film on a substrate, wherein a contact angle between the resist film and an immersion liquid is a first angle; forming a protective film on the resist film, wherein a contact angle between a surface of the protective film and the immersion liquid is a second angle lager than the first angle; forming a latent image in the resist film by immersion type exposure using the immersion liquid; modifying the surface of the protective film to form a low contact angle layer after forming the latent image, wherein a contact angle between the low contact angle layer and the immersion liquid is a third angle smaller than the second angle; removing the immersion liquid adsorbed or absorbed by the protective film after forming the low contact angle layer; heating the resist film after removing the immersion liquid; removing the protective film after removing the immersion liquid; and developing the resist film to form a resist pattern after heating the resist film and after removing the protective film.

According to a sixth aspect of the present invention, there is provided a method for manufacturing a semiconductor device, the method including: forming a resist film on a substrate; forming a protective film on the resist film, wherein a contact angle between a surface of the protective film and an immersion liquid is a first angle; forming a latent image in the resist film by immersion type exposure using the immersion liquid; etching the surface of the protective film to expose a new surface while modifying the newly exposed surface of the protective film to form a low contact angle layer, after forming the latent image, wherein a contact angle between a surface of the low contact angle layer and the immersion liquid is a second angle smaller than the first angle; removing the immersion liquid adsorbed or absorbed by the protective film after forming the low contact angle layer; heating the resist film after removing the immersion liquid; and developing the resist film to form a resist pattern after heating the resist film.

### BRIEF DESCRIPTION OF THE SEVERAL VIEWS OF THE DRAWING

FIG. 1 is a sectional view schematically showing a part of the process of a method for manufacturing a semiconductor device according to a first to third embodiments of the present invention;

FIG. 2 is a sectional view schematically showing a part of the process of the method for manufacturing a semiconductor device according to the first to third embodiments of the present invention;

FIG. 3 is a sectional view schematically showing a part of the process of the method for manufacturing a semiconductor device according to the first and third embodiments of the present invention;

FIG. 4 is a sectional view schematically showing a part of the process of the method for manufacturing a semiconductor device according to the first and third embodiments of the present invention;

FIG. 5 is a sectional view schematically showing a part of the process of the method for manufacturing a semiconductor device according to the first to third embodiments of the present invention;

FIG. 6 is a sectional view schematically showing a part of the process of the method for manufacturing a semiconductor device according to the first to third embodiments of the present invention;

FIG. 7 is a sectional view schematically showing a part of the process of the method for manufacturing a semiconductor device according to the second embodiment of the present invention;

FIG. 8 is a sectional view schematically showing a part of the process of the method for manufacturing a semiconductor device according to the second embodiment of the present invention;

FIG. 9 is a sectional view schematically showing a part of the process of the method for manufacturing a semiconductor device according to the second embodiment of the present invention;

FIG. 10 is a flowchart showing the procedure of a method for manufacturing a semiconductor device according to a fourth embodiment of the present invention;

FIGS. 11A to 11C are sectional views showing a process for manufacturing a semiconductor device according to the fourth embodiment of the present invention;

FIGS. 12A and 12B are diagrams showing a removing process of a cleaning fluid according to the fourth embodiment of the present invention;

FIG. 13 is a diagram schematically showing the configuration of an exposure apparatus according to a fourth to sixth embodiments of the present invention;

FIG. 14 is a plan view showing the order in which exposure fields are exposed according to the fourth to sixth embodiments of the present invention;

FIG. 15 is a plan view showing droplets remaining on a substrate after scan exposure according to the fourth to sixth embodiments of the present invention;

FIG. 16 is a flowchart showing the procedure of a method for manufacturing a semiconductor device according to a fifth embodiment of the present invention;

FIG. 17 is a flowchart showing the procedure of a method for manufacturing a semiconductor device according to a sixth embodiment of the present invention; and

FIGS. 18A and 18B are sectional views showing a process for manufacturing a semiconductor device according to the sixth embodiment of the present invention.

### DETAILED DESCRIPTION OF THE INVENTION

Embodiments of the present invention will be described with reference to the drawings.

### Embodiment 1

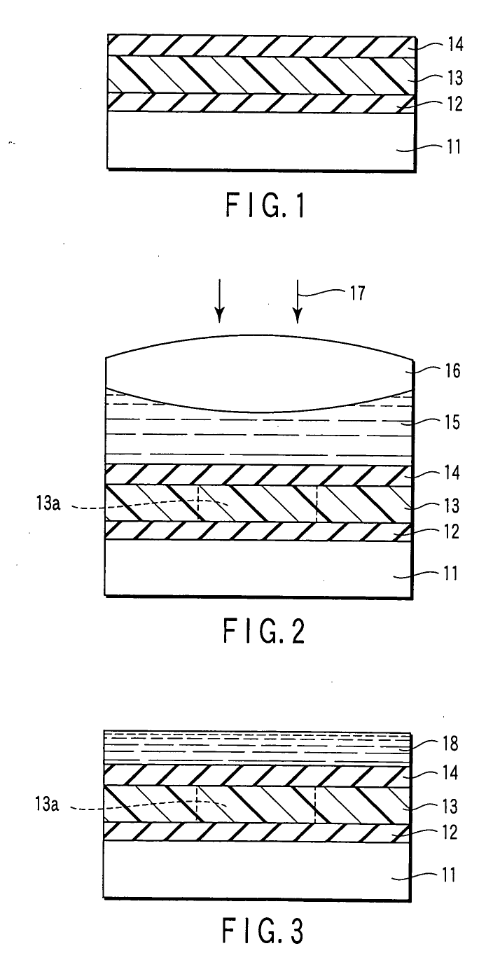

With reference to FIGS. 1 to 6, description will be given of a method for manufacturing a semiconductor device according to a first embodiment of the present invention.

First, as shown in FIG. 1, a substrate 11 is provided on which a semiconductor device such as an LSI is to be formed. The substrate 11 is, for example, a semiconductor substrate on which an insulating film, a conductive film, and the like are formed. Subsequently, a coating material for the formation of an antireflection coating is spin-coated on the substrate 11. The substrate 11 is further subjected to heating treatment to form an antireflection coating 12 of thickness about 50 nm. Subsequently, a chemically amplified resist film 13 for ArF excimer laser is formed on the antireflection coating 12; the resist film 13 contains a photo acid generating agent and has a thickness of about 200 nm. Specifically, a coating material for the formation of a chemically amplified resist film is spin-coated on the antireflection coating 12. The substrate is further subjected to heating treatment to remove a solvent contained in the coating material. A chemically amplified resist film 13 is thus formed.

Then, a protective film 14 is formed on the resist film 13. Specifically, a coating material (for example, TSP-3A manufactured by TOKYO OHKA KOGYO CO., LTD.) for a protective film is spin-coated on the resist film 13, the coating material contains a fluoro solvent and a fluoro polymer. Moreover, the solvent contained in the coating material is removed to form a protective film 14.

Then, as shown in FIG. 2, the substrate on which the resist film 13 and the protective film 14 are formed is conveyed to a scan exposure apparatus. Subsequently, an immersion lithography method is used to transfer (project) a pattern formed on a reticle (not shown) to the resist film 13. That is, the resist film 13 is irradiated with exposure light (ArF excimer laser) 17 with a liquid 15 for immersion lithography (in the present example, water (pure water)) interposed between the protective film 14 and a lens 16 of the exposure apparatus. This forms a latent image in an exposure area 13a of the resist film 13. During the immersion lithography, the resist film 13 can be protected from the immersion lithography liquid 15 because the protective film 14 has been formed between the resist film 13 and the immersion lithography liquid 15. That is, the protective film 14 is not dissolved into the immersion liquid 15 but prevents the immersion liquid 15 from permeating through the resist film 13. Consequently, the resist film 13 can be reliably protected from the immersion liquid 15. Subsequently, a heating treatment is executed to cause a reaction (referred to as a catalyst reaction below for convenience) using as a catalyst a photo acid generated in the chemically amplified resist film 13 by exposure. As a result, the exposed area 13a of the chemically amplified resist film 13 (in the present example, a positive resist) becomes dissoluble to an alkali solution. With a negative resist, the exposed area becomes insoluble to an alkali solution.

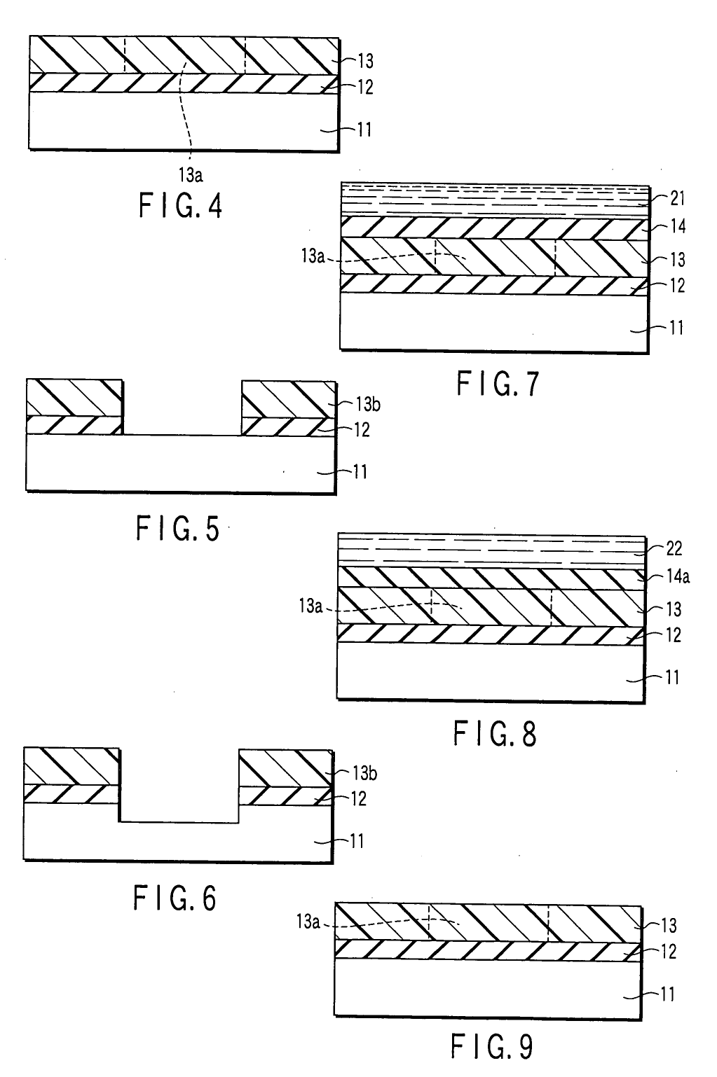

Then, as shown in FIG. 3, ozone water is supplied to the surface of the protective film 14 as an oxidative liquid (second liquid) 18. Thus, as shown in FIG. 4, the oxidizing action of the oxidative liquid 18 removes the protective film 14. On this occasion, the resist film 13 is not dissolved into the oxidative liquid 18 but remains on the substrate 11. Moreover, water (pure water) or hydrogen water is used to clean the surface of the resist film 13 to remove the oxidative liquid 18.

Then, as shown in FIG. 5, the resist film 13 is developed to form a resist pattern 13b. The developed is, for example, a TMAH (tetramethyl ammonium hydroxide) aqueous solution of concentration 2.38%. Moreover, the antireflection coating 12 is removed.

Subsequently, as shown in FIG. 6, the substrate 11 is partly etched using the resist pattern 13b as a mask. Further, the resist pattern 13b is removed to finish the series of steps.

As described above, according to the present embodiment, the protective film 14 is removed using the oxidative liquid 18 such as ozone water as a stripper. Thus, even with a protective film such as a fluoro polymer which has a sufficient protect function, it is unnecessary to construct a dedicated expensive waste water treatment system used to recover the stripper for the protective film. Therefore, the immersion lithography can be reliably and inexpensively carried out. This substantially suppresses an increase in the manufacturing costs of semiconductor devices.

In the above embodiment, ozone water is used as the oxidative liquid 18. However, it is possible to use a liquid containing at least one of ozone (O₃), oxygen (O₂), carbon monoxide (CO), and hydrogen peroxide (H₂O₂).

Further, in the above embodiment, ArF excimer laser (wavelength: 193 nm) is used as exposure light, but KrF excimer laser (wavelength: 248 nm) may be used. Alternatively, F₂ excimer laser (wavelength: 157 nm) may be used as exposure light. In this case, fluoro oil can be used as the immersion lithography liquid 15.

Further, in the above embodiment, after the exposure of the resist film 13, the heating treatment is executed to cause the catalyst reaction before the removal of the protective film 14. However, the heating treatment may be executed after the removal of the protective film 14 depending on the types of the resist film 13 and protective film 14.

### Embodiment 2

With reference to FIGS. 1, 2, 5, 6, 7, 8, and 9, description will be given of a method for manufacturing a semiconductor device according to a second embodiment of the present invention.

A procedure similar to that according to the first embodiment is executed until the step shown in FIG. 2. However, in the present embodiment, the protective film 14, formed on the resist film 13, is different from that according to the first embodiment. In the present embodiment, after the formation of the resist film 13, the protective film 14 is formed by spin-coating a solution for the formation of a protective film on the resist film 13, the solution containing of a copolymer of methylvinylether and maleic anhydride. Further, a heating treatment is performed to form a protective film 14. During immersion lithography, the protective film 14 can protect the resist film 13 from the liquid 15 (first liquid, in the present example, water (pure water)) for immersion lithography interposed between the protective film 14 and a lens 16 for exposure.

After the step shown in FIG. 2, a 0.1-N HCl aqueous solution is placed on the protective film 14 as an acid liquid (second liquid) 21 and is then left as it is for 30 seconds, as shown in FIG. 7. This converts the maleic anhydride into maleic acid to modify the protective film 14.

Then, as shown in FIG. 8, a tetramethyl ammonium hydroxide aqueous solution of concentration 0.5% is fed onto the modified protective film 14a as an alkali liquid 22 (third liquid) using a spray method. Thus, as shown in FIG. 9, the modified protective film 14a is removed. The resist film 13 is not dissolved into the liquid 22 but remains on the substrate 11.

Subsequently, the developing step shown in FIG. 5 and the etching step shown in FIG. 6 are executed as in the case of the first embodiment to finish the series of steps.

As described above, according to the present embodiment, the protective film 14 is modified and the modified protective film 14a is removed. Thus, even with a protective film having a sufficient protect function, it is unnecessary to construct a dedicated expensive waste water treatment system used to recover the stripper for the protective film. Therefore, the immersion lithography can be reliably and inexpensively carried out. This substantially suppresses an increase in the manufacturing costs of semiconductor devices.

In the above embodiment, the type of the liquid (second liquid) 21 used to modify the protective film 14 may be different from that of the liquid 22 (third liquid) used to remove the modified protective film 14a. If the liquids are of the same type, they may have different concentrations. Furthermore, the liquid 21 used to modify the protective film 14 may generally be alkali, acid, oxidative, or reductive. The liquid 22 used to remove the modified protective film 14a may generally be alkali, acid, oxidative, or reductive.

Further, as in the case of the first embodiment, the heating treatment for causing a catalyst reaction may be executed before or after the removal of the protective film 14.

### Embodiment 3

With reference to FIGS. 1 to 6, description will be given of a method for manufacturing a semiconductor device according to a third embodiment of the present invention.

First, a procedure similar to that according to the first embodiment is executed until the step shown in FIG. 2. However, in the present embodiment, alkyl silsesquoxane, having a molecular weight of less than 1000, is used as a material for the protective film 14, formed on the resist film 13. Using alkyl silsesquoxane as the protective film 14 enables the resist film 13 to be protected from the immersion liquid (in the present example, water (pure water)) 15, interposed between the protective film 14 and the lens 16 for exposure. That is, if immersion lithography is carried out, the immersion lithography liquid 15 is maintained at room temperature (about 24° C., first temperature) in order to stabilize the characteristics of an optical system in the exposure apparatus. The protective film 14 is formed of alkyl silsesquoxane, having a molecular weight of less than 1000, and is thus not dissolved into water at room temperature (about 24° C.). This enables the resist film 13 to be reliably protected from the immersion liquid (water) 15.

After the step shown in FIG. 2, a liquid (second liquid) 18 is supplied to the surface of the protective film 14 as shown in FIG. 3; the second liquid 18 is of the same type as that of the immersion liquid 15 and has a temperature (second temperature) higher than that of the immersion lithography liquid 15. In the present example, water (pure water) is supplied to the surface of the protective film 14. The temperature of the liquid (pure water) 18 has only to be enough to dissolve and remove the protective film 14. However, the temperature is preferably as high as possible in order to facilitate the dissolution and removal of the protective film 14. Thus, as shown in FIG. 4, the protective film 14 is removed and the resist film 13 remains on the substrate 11 without being dissolved into the liquid 18.

Subsequently, the developing step shown in FIG. 5 and the etching step shown in FIG. 6 are performed as in the case of the first embodiment to finish the series of steps.

As described above, according to the present embodiment, the immersion liquid 15 is maintained at a temperature at which the protective film 14 is not dissolved, whereas the liquid 18 used to strip off the protective film 14 is maintained at a temperature at which the protective film 14 can be dissolved. This makes it possible to use water or the like as the liquid 18 used to strip off the protective film 14. Thus, even with a protective film having a sufficient protect function, it is unnecessary to construct a dedicated expensive waste water treatment system used to recover the stripper for the protective film. Therefore, the immersion lithography can be reliably and inexpensively carried out. This substantially suppresses an increase in the manufacturing costs of semiconductor devices.

Further, as in the case of the first embodiment, the heating treatment for causing a catalyst reaction may be executed before or after the removal of the protective film 14.

As described above, the first to third embodiments have the following methods.

(a1) A method for manufacturing a semiconductor device, the method comprising: forming a resist film on a substrate; forming a protective film on the resist film; exposing the resist film with a first liquid interposed between the protective film and a lens for exposure; removing the protective film using an oxidative second liquid after exposing the resist film; and developing the resist film to form a resist pattern after removing the protective film.

(a2) In the method a1, the second liquid contains at least one of ozone, oxygen, carbon monoxide, and hydrogen peroxide.

(a3) A method for manufacturing a semiconductor device, the method comprising: forming a resist film on a substrate; forming a protective film on the resist film; exposing the resist film with a first liquid interposed between the protective film and a lens for exposure; modifying the protective film using a second liquid after exposing the resist film; removing the modified protective film using a third liquid; and developing the resist film to form a resist pattern after removing the modified protective film.

(a4) The method a1 or a3 further comprising carrying out cleaning using water or hydrogen water after removing the protective film.

(a5) A method for manufacturing a semiconductor device, the method comprising: forming a resist film on a substrate; forming a protective film on the resist film; exposing the resist film with a first liquid at a first temperature interposed between the protective film and a lens for exposure; removing the protective film using a second liquid after exposing the resist film, the second liquid being of the same type as that of the first liquid and having a second temperature higher than the first temperature; and developing the resist film to form a resist pattern after removing the protective film.

(a6) In the method as, the first and second liquids are water.

(a7) The method a1, a3, or a5 further comprises executing a heating treatment after exposing the resist film and before forming the resist pattern.

(a8) In the method a7, the heating treatment is executed before removing the protective film.

(a9) In the method a7, the heating treatment is executed after removing the protective film.

(a10) The method a1, a3, or a5 further comprises etching a part of the substrate using the resist pattern as a mask.

### Embodiment 4

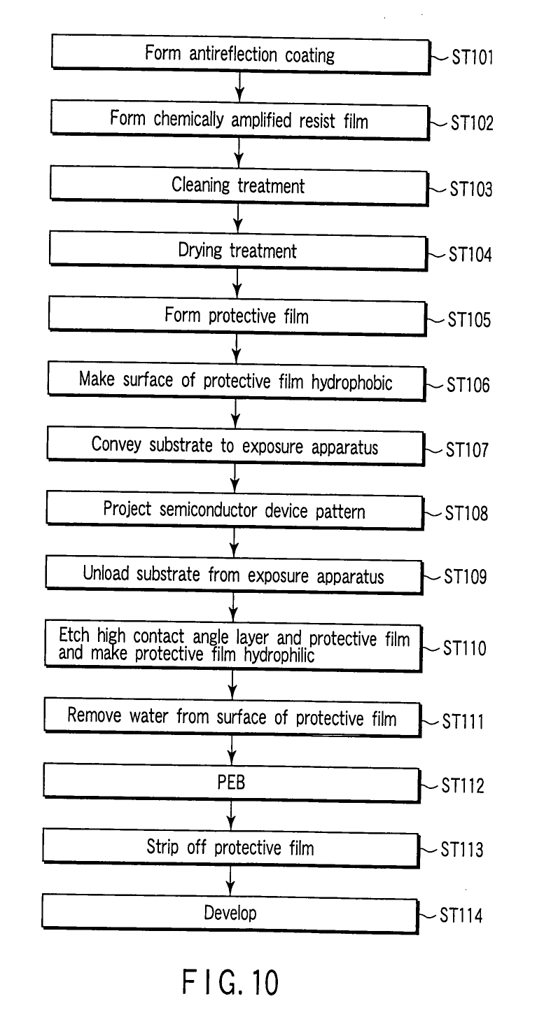

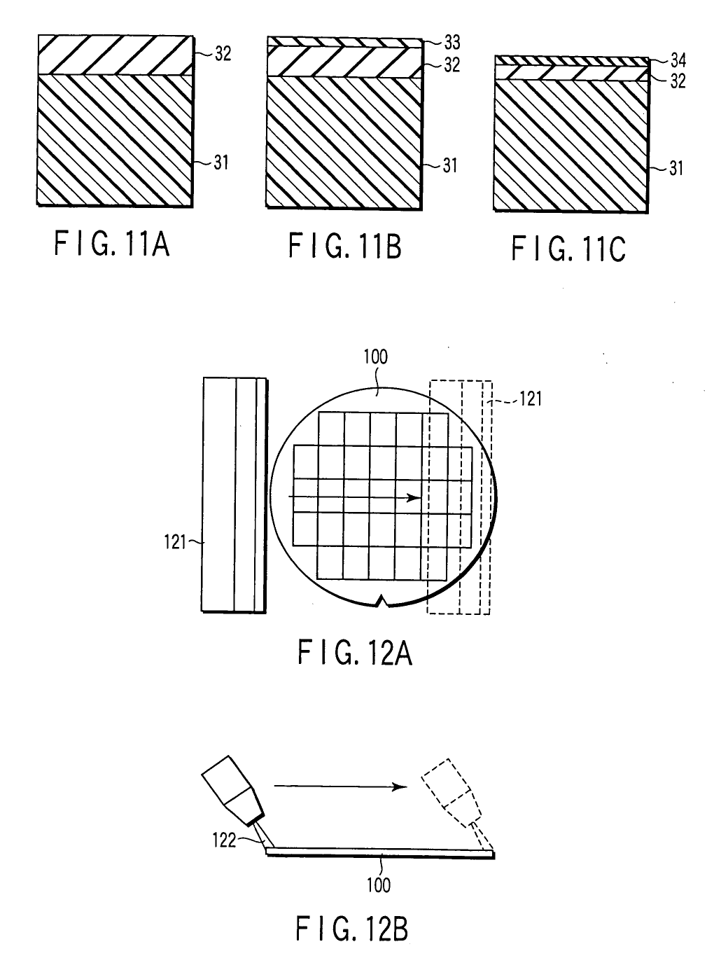

Now, with reference to FIGS. 10 and 11A to 11C, description will be given of a method for manufacturing a semiconductor device according to a fourth embodiment of the present invention. FIG. 10 is a flowchart showing the procedure of a process for manufacturing a semiconductor device according to the present embodiment. Deionized water is used as an immersion liquid. FIGS. 11A to 11C are sectional views showing the process for manufacturing a semiconductor device according to the present embodiment.

First, a coating material for an antireflection coating is dropped on a semiconductor wafer (not shown). Subsequently, the spin coat method is used to spread the coating material over the wafer, which is then subjected to heating treatment to form an antireflection coating of thickness about 50 nm (step ST101). Subsequently, an ArF chemically amplified resist film containing an acid generating agent is formed on the antireflection coating to a film thickness of about 200 nm (step ST102). The chemically amplified resist film is formed using the following procedure. First, the spin coat method is used to spread the coating material for the chemically amplified resist over the antireflection film. Then, a heating treatment is executed to remove the solvent contained in the coating material.

Surface analysis separately executed on the ArF chemically amplified resist film indicates that the oxygen generating agent and an acid trap agent (amine or the like) are distributed over the film surface. Thus, to remove the acid generating agent and acid trap agent on the resist film surface, cleaning fluid (deionized water) is fed onto the resist film for a cleaning treatment (step ST103). The cleaning fluid is desirably deionized water, pure water, hydrogen water, carbonated water, or the like. Any of these fluids may be used depending on the physical properties of substances adhering to the film surface. Hydrogen water was effective on the adsorbed substances hydrogen-bonded to the film surface. Further, carbonated water was effective on charged adsorbed substances. The cleaning removes the acid generating agent and acid trap agent from the resist film surface.

After the cleaning step, the resist film surface is dried (step ST104). Spin drying may be used for the drying treatment. However, as shown in FIGS. 12A and 12B, an air knife (air curtain) may be used which has an air discharge port with a length equal to or larger than the diameter of the substrate. Specifically, Acid and alkali filtered gas 122 from the air knife 121 is blown against the principal surface of the substrate 100. The area against which air 122 from the air knife 121 is blown is a part of the surface of the substrate 100. Thus, the air knife 121 is scanned from one end toward the other end of the surface of the substrate 100 in order to blow air against the entire surface of the substrate 100. On this occasion, the substrate 100 may be rotated or may be stationary. If no acid generating agent or acid trap agent (amine or the like) is present on the surface of the ArF chemically amplified resist film, steps ST103 and ST104 may be omitted.

Moreover, as shown in FIG. 11A, the spin coat method is used to form a protective film 32 on the ArF chemically amplified resist film 31 (having a contact angle of 750 at which the resist film contacts deionized water (immersion liquid)) to a film thickness of about 20 nm (step ST105). The protective film is coated so that the resist film and antireflection coating formed on the substrate will not contact the immersion liquid during the subsequent exposure step. If a water-dissolvable substance is present on the surface of the protective film 32, the cleaning and drying treatments are preferably executed as in the case of steps ST103 and ST104. The cleaning fluid used for the cleaning treatment is preferably selected depending on the substances present on the protective film 32.

The contact angle between the protective film 32 and deionized water, which is an immersion liquid, is about 70°. Before immersion lithography, a hydrophobic layer (high contact angle layer) 33 is formed on the surface of the protective film 32 as shown in FIG. 11B; the hydrophobic layer 33 has a contact angle of larger than 75° at which the hydrophobic layer 33 contacts the deionized water (step ST106). The hydrophobic layer 33 is formed by modifying the surface of the protective film 32. Specifically, the surface of the protective film 32 is modified by maintaining the substrate temperature at about 80° C. and exposing the surface of the protective film 32 to a hexamethyl disilazane atmosphere. The surface of the protective film 32 is preferably modified so that the contact angle between the hydrophobic layer 33 and the deionized water is at least 80°. To form a hydrophobic layer 33, the surface of the protective film 32 may be modified by exposing the surface of the protective film 32 to a liquid or atmosphere of an organic silazane compound or fluorine compound.

An object of the hydrophobic layer 33 formed on the surface of the hydrophilic protective film 32 is to prevent the deionized water from permeating through the protective film 32. Another object of the hydrophobic layer 33 is to inhibit the deionized water from remaining on the surface of the protective film during exposure.

The contact angle between the protective film 32 and the deionized water is smaller than that between the resist film 31 and the deionized water. Accordingly, even if the deionized water permeated during immersion lithography, the permeating deionized water would be trapped by the protective film 32, which is hydrophilic. If the contact angle at which the protective film contacts the deionized water is at least 80°, step ST106 may be omitted.

Then, the substrate is conveyed to a scan exposure apparatus (step ST107). Subsequently, the scan exposure apparatus is used to transfer (project) a semiconductor element pattern formed on a reticle to the resist film. Thus, a latent image is formed (step ST108).

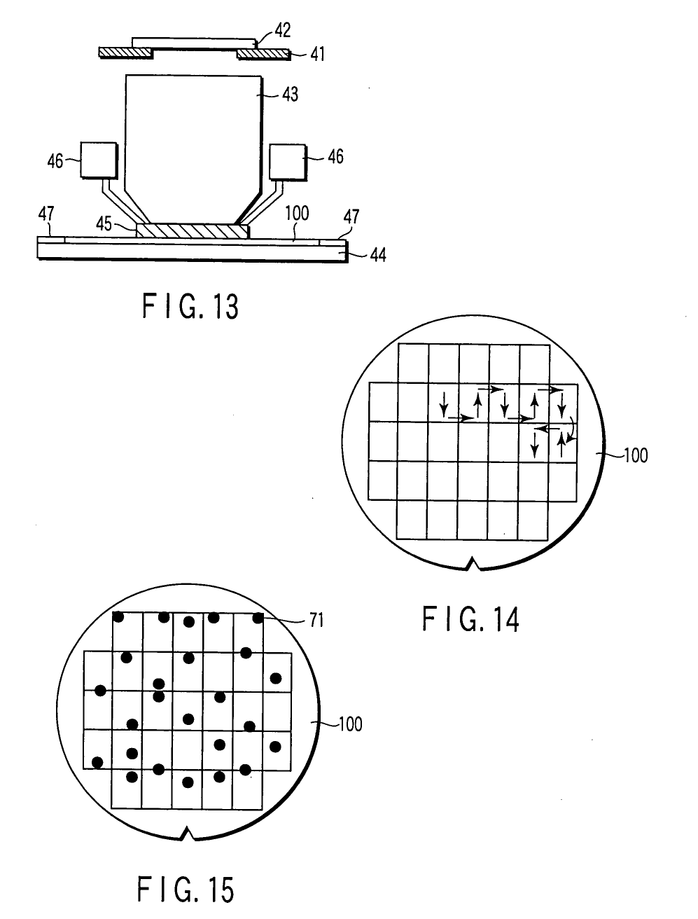

FIG. 13 is a diagram schematically showing the configuration of an immersion exposure apparatus used in the present embodiment. A reticle stage 41 is placed below an illumination optical system (not shown). A reticle 42 is placed on the reticle stage 41. The reticle stage 41 can be moved parallel. A projection lens system 43 is placed below the reticle stage 41. A wafer stage 44 is placed below the projection lens system 43. A semiconductor substrate 100 on which the above treatment has been executed is installed on the wafer stage 44. The wafer stage 44 moves parallel together with the semiconductor substrate 100. A support plate 47 is provided around the semiconductor substrate 100.

A fence 45 is attached to under the projection lens system 43. A pair of water supply and drainage devices 46 is provided to feed deionized water (immersion liquid) into the fence 45 and to drain the deionized water from the fence 45. During exposure, the liquid film of the deionized water fills the space surrounded by the fence 45 and projection lens system 43 (the space between the substrate 100 and the projection lens system 43). Exposure light emitted by the projection lens system 43 passes through the layer of the deionized water to an irradiated area. An image of a mask pattern (not shown) formed on the reticle 42 is projected on the irradiated area on the photoresist, formed on the substrate surface. Thus, a latent image is formed.

FIG. 14 is a plan view showing an example of an exposure order used when exposure fields are sequentially scanned and exposed. The arrows shown in FIG. 14 indicate the directions in which an exposure slit area moves. As shown in FIG. 14, after one exposure field is scanned and exposed, the direction of the scan is reversed when the next exposure field is scanned and exposed. The entire surface of the substrate is exposed while repeating the above operation.

After exposure is thus carried out, the substrate is conveyed from the scan exposure apparatus (step ST109).

During the scan exposure, the water supply and drainage devices 46 recover the deionized water so that no deionized water remains outside the area surrounded by the fence 45. However, if the stage moves at a high speed or is markedly accelerated or the exposed area is relatively large, water 71 remains on the protective film 32 of the substrate 100 as shown in FIG. 15. The water 71 remaining on the protective film 32 may cause the deionized water to be adsorbed by the surface of the protect layer 32 or to permeate through the protective film 32, which thus absorbs the water. If a heating (post-exposure baking) operation is performed with the deionized water adsorbed or absorbed by the protective film 32, heat is absorbed by the areas having adsorbed or absorbed the deionized water. Thus, these areas supply a smaller quantity of heat to the resist film 31 than the other areas. As a result, a thermal reaction cannot be sufficiently produced in the resist film 31, resulting in the abnormal line width of the resist pattern. With a positive resist, failure-to-open defects may occur. With a negative resist, bad-open defects may occur.

To solve this problem, the remaining water 71 and the deionized water must be removed from the substrate unloaded from the exposure apparatus; the remaining water 71 has remained on the protective film 32 and the deionized water has been absorbed by the protective film 32. However, since the hydrophobic layer 33 is formed on the surface of the protective film 32, it is difficult to remove, from the protective film 32, the water absorbed by the protective film 32. Insufficient water removal may result in the likelihood of the formation of water marks during a water removing step. The dimensions may vary in areas with water marks.

Thus, the hydrophobic layer (high contact angle layer) 33 is etched away and the surface of the protective film 32 is made hydrophilic (step ST110). A making-hydrophilic treatment is executed by feeding ozone water onto the protective film 32 for about 30 seconds, the ozone water having an ozone concentration of about 20 ppm. Any ozone concentration may be used provided that it enables the hydrophobic layer 33 to be removed and prevents the resist film from being damaged. The hydrophobic layer 33 is removed by the ozone water. The exposure of the surface of the protective film 32 makes the etched surface hydrophilic while etching the surface of the protective film 32. Thus, a hydrophilic layer (low contact angle layer) 34 is formed (FIG. 11C).

After the above treatment, the thickness of the protect layer 32 was 5 nm, and the contact angle between the surface of the hydrophilic layer 34 and the deionized water was at most 5°. In the present embodiment, the contact angle (5°) between the hydrophilic layer 34 and the deionized water is smaller than that (75°) between the resist film 31 and the deionized water. The contact angle (5°) between the hydrophilic layer 34 and the deionized water is preferably smaller than that (70°) between the protective film 32 and the deionized water.

An object of the etching of the surface of the protective film 32 is to remove water marks resulting from drying of the deionized water remaining on the protective film during exposure. Another object of the etching is to reduce the time required for the removal in the subsequent step of removing the protective film 32. In the present step, the whole protective film 32 may be etched away. In this case, in the latter half of the etching, the ozone concentration of the ozone water is preferably reduced to avoid damaging the resist film 31.

If the protective film 32 cannot sufficiently trap the deionized water, so that the deionized water permeates through the resist film 31 during immersion lithography, then the following deionized water is removed: the deionized water present on and in the protective film and the deionized water having permeated through the resist film. This treatment need not be executed if the protective film 32 can sufficiently trap the deionized water, so that the deionized water does not permeate through the resist film 31.

According to the present embodiment, the treatment described below is executed in order to carry out drying without making water marks. A liquid film (first liquid film) is formed substantially all over the surface of the substrate. As in the case of the drying after the cleaning treatment, spin drying or an air knife is used to remove the first liquid film (step ST111). This treatment removes all of the water (remaining water+first liquid film) on the film surface. A chemical used for the first liquid film is preferably deionized water. However, it is possible to use a chemical which has an affinity for deionized water, an immersion liquid, which does not damage the resist film, and which produces less heat of vaporization than that of the immersion liquid (in the present embodiment, the deionized water produces heat of vaporization=583 cal/g at 100° C.). Alcohol or ether, for example, may be used. It is also possible to use these chemicals dissolved into a solvent containing the same components as those of the immersion liquid. More preferably, the chemical used dries quickly.

The substrate on which the above treatment has been executed is conveyed to a baker, where the treated substrate is subjected to post-exposure baking (PEB) (step ST112). This thermal step diffuses an acid resulting from exposure and causes an amplification reaction.

Then, if the protective film 32 is present on the resist film surface, it is removed. If the protective film is dissolvable to a developer, the protective film may be removed during development (step ST113). Moreover, the treated substrate is conveyed to a developing unit for development. Thus, an ArF resist pattern is formed (step ST114).

The atmosphere must be controlled at least during the steps in which the substrate moves from the exposure unit through the succeeding water treatment unit to the baker unit. It has been found that the concentration of a basic substance must be set to at most 10 ppb in order to suppress inactivation of an acid while preventing the formation of a resist pattern from being affected. Further, the results of experiments indicate that the treatment time including the conveyance time is desirably controlled to within the variation range of ±10%.

According to the present embodiment, before immersion lithography, the protective film, which is more hydrophilic than the resist film, is made hydrophobic. This makes it possible to hinder deionized water from permeating through the resist film during immersion lithography. Moreover, after immersion lithography, the surface of the protective film is made hydrophilic and the deionized water is removed. Consequently, the water remaining at the protective film can be removed without making any water marks. As a result, it is possible to suppress the inappropriate formation of a pattern.

In the present embodiment, deaerated deionized water is used as an immersion liquid. However, the present embodiment is not limited to this. A liquid to which an alkali ion of a group I or II element is added may be used as an immersion liquid in order to increase refractive index. Further, a liquid to which acid ions are added may be used as an immersion liquid in order to reduce an absorption coefficient. Any liquid can be used as an immersion liquid provided that it exhibits a small absorption coefficient with respect to exposure light, has a particular refractive index (if an exposure apparatus used is adapted for the particular refractive index), and does not damage the lens system or the like.

Further, in the present embodiment, exposure using ArF light (193 nm) has been described. However, a treatment similar to that described above enables precise patterning to be achieved by exposure using KrF light (248 nm). It has also been found that the use of fluorine-based oil as a first solvent enables precise patterning to be achieved by exposure using F₂ light (157 nm).

### Embodiment 5

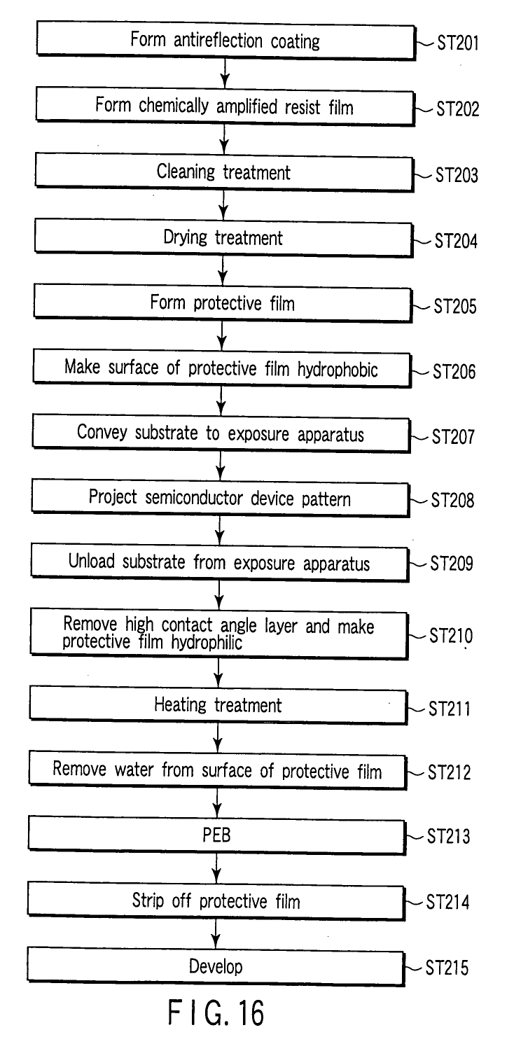

Now, with reference to FIG. 16, description will be given of a method for manufacturing a semiconductor device according to a fifth embodiment of the present invention. FIG. 16 is a flowchart showing the procedure of a process for manufacturing a semiconductor device according to the present embodiment.

Steps ST201 to ST209 are similar to steps ST101 to ST109, described in the fourth embodiment. Accordingly, the description of steps ST201 to ST209 is omitted and step ST210 will be described first.

The hydrophobic layer (high contact angle layer) on the protective film is removed. In this step, a making-hydrophilic treatment is also executed on the surface of the protective film (step ST210). In this case, the hydrophobic layer is removed and the surface of the protective film made hydrophilic using ozone water having an ozone concentration of about 10 ppm in the solution. Any ozone concentration may be used provided that it enables the protective film to be modified and prevents the resist film from being damaged. Since the protective film is intrinsically very hydrophilic, the removal of the hydrophobic layer has only to be carried out without executing the treatment of making the protective film hydrophilic.

Then, a heating treatment is executed to remove the deionized water having permeated through the protective film (step ST211). In this case, the substrate is heated at a temperature (for example, 90° C.) at which the deionized water used as an immersion liquid is not boiled. A sucker may be placed above the protective film 32 to suck water having permeated through the protective film 32 and resist film 31. Further, heating and sucking may be combined together. Furthermore, water may be removed by reduced pressure drying. Heating, suction, and reduced pressure drying may be combined together.

If the protective film 32 cannot sufficiently trap the deionized water, so that the deionized water permeates through the resist film 31 during immersion lithography, then the following deionized water is removed: the deionized water present on and in the protective film and the deionized water having permeated through the resist film. This treatment need not be executed if the protective film 32 can sufficiently trap the deionized water, so that the deionized water does not permeate through the resist film 31. Further, if the water does not remain on the hydrophobic layer on the protective film, the deionized water does not permeate through the protective film. This eliminates the need for the treatment for removing the deionized water having permeated through the protective film.

The treatment in subsequent steps ST212 to ST215 is similar to that in steps ST111 to ST114, described in the fourth embodiment. Accordingly, the description of this treatment is omitted.

### Embodiment 6

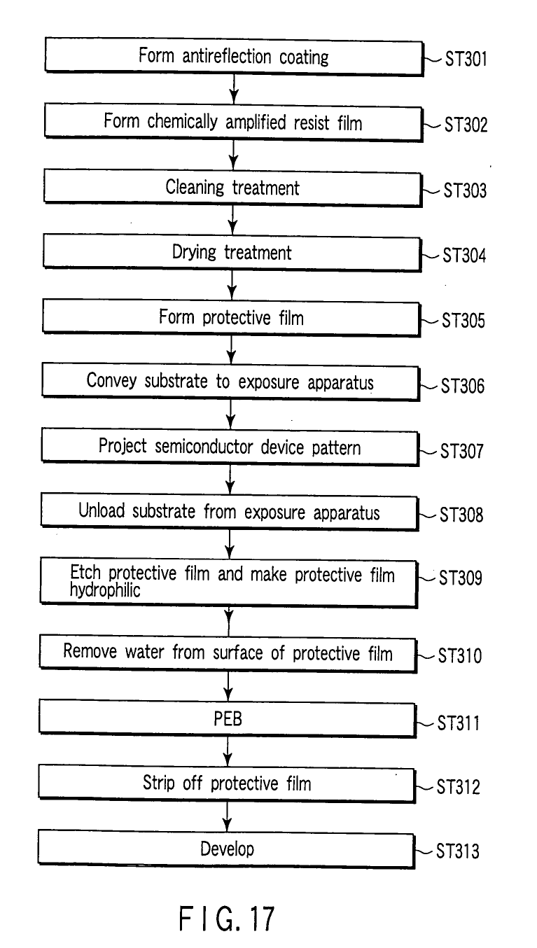

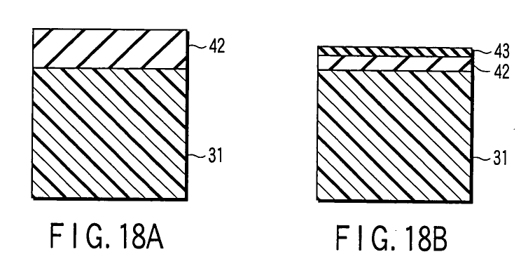

Now, with reference to FIGS. 17, 18A, and 18B, description will be given of a method for manufacturing a semiconductor device according to a sixth embodiment of the present invention. FIG. 17 is a flowchart showing the procedure of a process for manufacturing a semiconductor device according to the present embodiment. FIGS. 18A and 18B are sectional views showing a process of manufacturing a semiconductor device according to the present embodiment.

Steps ST301 to ST304 are similar to steps ST101 to ST104, described in the fourth embodiment. Accordingly, the description of steps ST301 to ST304 is omitted and step ST305 will be described first.

As shown in FIG. 18A, a protective film 42 is formed on the resist film 31 (step ST305). The protective film 42 is formed so that the contact angle between the protective film 42 and deionized water, used as an immersion liquid, is larger than that between the resist film 31 and the deionized water. Owing to the large contact angle between the surface of the protective film 42 and the deionized water, the deionized water is hindered from permeating through the protective film 42 during the subsequent immersion lithography. Before immersion lithography, the surface of the protective film 42 may be modified so as to form a hydrophobic layer having a contact angle larger than that between the protective film 42 and the deionized water.

Steps ST306 to ST308 are similar to steps ST107 to ST109, described in the fourth embodiment. Accordingly, the description of steps ST306 to ST308 is omitted and step ST309 will be described. As in the case of step ST110 of the fourth embodiment, the surface of the protective film 42 is etched, while the etched surface is made hydrophilic to form a hydrophilic layer 43. In this treatment, deionized water adsorbed by the surface of the protective film and permeating through the protective film in the immersion lithography is removed. This making-hydrophilic treatment is executed so that the contact angle between the hydrophilic layer 43 and the deionized water is smaller than that between the protective film 42 and the deionized water.

After the surface of the protective film is made hydrophilic, heating, suction, reduced pressure drying, or any combination thereof may be used to remove the deionized water having permeated through the protective film, as in the case of the fifth embodiment.

Further, if the deionized water does not permeate through the protective film during immersion lithography, it neither permeates through the resist film. Consequently, only the deionized water adsorbed by the surface of the protective film is removed. However, when the deionized water permeates through the protective film, it may also permeate through the resist film. In this case, the deionized water present on and in the protective film and in the resist film is removed. To remove the deionized water from the resist film, it is preferable to set the contact angle between the surface of the protective film made hydrophilic and the deionized water smaller than that between the resist film and the deionized water. Reducing the contact angle facilitates the removal of the deionized water from the resist film.

The steps following step ST309, that is, steps ST310 to ST313, are similar to steps ST111 to ST114, described in the fourth embodiment. Accordingly, the description of steps ST310 to ST313 is omitted.

As described above, the fourth to sixth embodiments have the following methods.

(b1) A method for manufacturing a semiconductor device, the method comprising: forming a resist film on a substrate, wherein a contact angle between the resist film and an immersion liquid is a first angle; forming a protective film on the resist film, wherein a contact angle between a surface of the protective film and the immersion liquid is a second angle smaller than the first angle; modifying the surface of the protective film to form a high contact angle layer, wherein a contact angle between the high contact angle layer and the immersion liquid is a third angle larger than the second angle; forming a latent image in the resist film by immersion type exposure using the immersion liquid after forming the high contact angle layer; heating the resist film after forming the latent image; removing the high contact angle layer after forming the latent image; removing the protective film after removing the high contact angle layer; and developing the resist film to form a resist pattern after heating the resist film and after removing the protective film.

(b2) In the method b1, the high contact angle layer is formed by exposing the surface of the protective film to a liquid or atmosphere of an organic silazane compound or a fluorine compound.

(b3) In the method b2, the organic silazane compound is hexamethyl disilazane, tetramethyl disilazane, or trimethyl disilazane.

(b4) The method b1 further comprises modifying the surface of the protective film to form a low contact angle layer after removing the high contact angle layer and before heating the resist film, wherein a contact angle between the low contact angle layer and the immersion liquid is a fourth angle smaller than the second angle; and removing the immersion liquid adsorbed or absorbed by the protective film after forming the low contact angle layer and before heating the resist film.

(b5) In the method b4, forming the low contact angle layer includes etching the surface of the protective film to expose a new surface.

(b6) A method for manufacturing a semiconductor device, the method comprising: forming a resist film on a substrate, wherein a contact angle between the resist film and an immersion liquid is a first angle; forming a protective film on the resist film, wherein a contact angle between a surface of the protective film and the immersion liquid is a second angle lager than the first angle; forming a latent image in the resist film by immersion type exposure using the immersion liquid; modifying the surface of the protective film to form a low contact angle layer after forming the latent image, wherein a contact angle between the low contact angle layer and the immersion liquid is a third angle smaller than the second angle; removing the immersion liquid adsorbed or absorbed by the protective film after forming the low contact angle layer; heating the resist film after removing the immersion liquid; removing the protective film after removing the immersion liquid; and developing the resist film to form a resist pattern after heating the resist film and after removing the protective film.

(b7) A method for manufacturing a semiconductor device, the method comprising: forming a resist film on a substrate; forming a protective film on the resist film, wherein a contact angle between a surface of the protective film and an immersion liquid is a first angle; forming a latent image in the resist film by immersion type exposure using the immersion liquid; etching the surface of the protective film to expose a new surface while modifying the newly exposed surface of the protective film to form a low contact angle layer, after forming the latent image, wherein a contact angle between a surface of the low contact angle layer and the immersion liquid is a second angle smaller than the first angle; removing the immersion liquid adsorbed or absorbed by the protective film after forming the low contact angle layer; heating the resist film after removing the immersion liquid; and developing the resist film to form a resist pattern after heating the resist film.

(b8) In the method b4, b6, or b7, removing the immersion liquid includes removing the immersion liquid absorbed by the resist film.

(b9) In the method b4, b6, or b7, the low contact angle layer is formed by exposing the surface of the protective film to a liquid or gas containing ozone.

(b10) The method b1, b6, or b7 further comprises etching a part of the substrate using the resist pattern as a mask.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for manufacturing a semiconductor device, the method comprising:
forming a resist film on a substrate;
forming a protective film on the resist film;
exposing the resist film with a first liquid interposed between the protective film and a lens for exposure;
removing the protective film using an oxidative second liquid after exposing the resist film; and
developing the resist film to form a resist pattern after removing the protective film.

2. The method according to claim 1, wherein the second liquid contains at least one of ozone, oxygen, carbon monoxide, and hydrogen peroxide.

3. The method according to claim 1, further comprising carrying out cleaning using water or hydrogen water after removing the protective film.

4. The method according to claim 1, further comprising executing a heating treatment after exposing the resist film and before forming the resist pattern.

5. A method for manufacturing a semiconductor device, the method comprising:
forming a resist film on a substrate;
forming a protective film on the resist film;
exposing the resist film with a first liquid interposed between the protective film and a lens for exposure;
modifying the protective film using a second liquid after exposing the resist film;
removing the modified protective film using a third liquid; and
developing the resist film to form a resist pattern after removing the modified protective film.

6. The method according to claim 5, further comprising carrying out cleaning using water or hydrogen water after removing the modified protective film.

7. The method according to claim 5, further comprising executing a heating treatment after exposing the resist film and before forming the resist pattern.

8. A method for manufacturing a semiconductor device, the method comprising:
forming a resist film on a substrate;
forming a protective film on the resist film;
exposing the resist film with a first liquid at a first temperature interposed between the protective film and a lens for exposure;
removing the protective film using a second liquid after exposing the resist film, the second liquid being of the same type as that of the first liquid and having a second temperature higher than the first temperature; and
developing the resist film to form a resist pattern after removing the protective film.

9. The method according to claim 8, wherein the first and second liquids are water.

10. The method according to claim 8, further comprising executing a heating treatment after exposing the resist film and before forming the resist pattern.

11. A method for manufacturing a semiconductor device, the method comprising:
forming a resist film on a substrate, wherein a contact angle between the resist film and an immersion liquid is a first angle;
forming a protective film on the resist film, wherein a contact angle between a surface of the protective film and the immersion liquid is a second angle smaller than the first angle;
modifying the surface of the protective film to form a high contact angle layer, wherein a contact angle between the high contact angle layer and the immersion liquid is a third angle larger than the second angle;
forming a latent image in the resist film by immersion type exposure using the immersion liquid after forming the high contact angle layer;
heating the resist film after forming the latent image;
removing the high contact angle layer after forming the latent image;
removing the protective film after removing the high contact angle layer; and
developing the resist film to form a resist pattern after heating the resist film and after removing the protective film.

12. The method according to claim 11, wherein the high contact angle layer is formed by exposing the surface of the protective film to a liquid or atmosphere of an organic silazane compound or a fluorine compound.

13. The method according to claim 11, further comprising:
modifying the surface of the protective film to form a low contact angle layer after removing the high contact angle layer and before heating the resist film, wherein a contact angle between the low contact angle layer and the immersion liquid is a fourth angle smaller than the second angle; and
removing the immersion liquid adsorbed or absorbed by the protective film after forming the low contact angle layer and before heating the resist film.

14. The method according to claim 13, wherein forming the low contact angle layer includes etching the surface of the protective film to expose a new surface.

15. A method for manufacturing a semiconductor device, the method comprising:
forming a resist film on a substrate, wherein a contact angle between the resist film and an immersion liquid is a first angle;
forming a protective film on the resist film, wherein a contact angle between a surface of the protective film and the immersion liquid is a second angle lager than the first angle;
forming a latent image in the resist film by immersion type exposure using the immersion liquid;
modifying the surface of the protective film to form a low contact angle layer after forming the latent image, wherein a contact angle between the low contact angle layer and the immersion liquid is a third angle smaller than the second angle;
removing the immersion liquid adsorbed or absorbed by the protective film after forming the low contact angle layer;
heating the resist film after removing the immersion liquid;
removing the protective film after removing the immersion liquid; and
developing the resist film to form a resist pattern after heating the resist film and after removing the protective film.

16. The method according to claim 15, wherein removing the immersion liquid includes removing the immersion liquid absorbed by the resist film.

17. The method according to claim 15, wherein the low contact angle layer is formed by exposing the surface of the protective film to a liquid or gas containing ozone.

18. A method for manufacturing a semiconductor device, the method comprising:
forming a resist film on a substrate;
forming a protective film on the resist film, wherein a contact angle between a surface of the protective film and an immersion liquid is a first angle;
forming a latent image in the resist film by immersion type exposure using the immersion liquid;
etching the surface of the protective film to expose a new surface while modifying the newly exposed surface of the protective film to form a low contact angle layer, after forming the latent image, wherein a contact angle between a surface of the low contact angle layer and the immersion liquid is a second angle smaller than the first angle;
removing the immersion liquid adsorbed or absorbed by the protective film after forming the low contact angle layer;
heating the resist film after removing the immersion liquid; and
developing the resist film to form a resist pattern after heating the resist film.

19. The method according to claim 18, wherein removing the immersion liquid includes removing the immersion liquid absorbed by the resist film.

20. The method according to claim 18, wherein the low contact angle layer is formed by exposing the surface of the protective film to a liquid or gas containing ozone.
